(19) United States
(12) Patent Application Publication
(10) Pub. No.: US 2024/0377100 A1
(43) Pub. Date: Nov. 14, 2024

(54) FLUID HEATING HEATER

(71) Applicant: Cha You LIM, Daejeon (KR)

(72) Inventor: Cha You LIM, Daejeon (KR)

(21) Appl. No.: 18/569,294

(22) PCT Filed: Oct. 17, 2022
(86) PCT No.: PCT/KR2022/015722

§ 371 Date: Dec. 12, 2023

(30) Foreign Application Priority Data
Nov. 19, 2021 (KR) 10-2021-0159945

(51) Int. Cl. F24H 1/10; B60H 1/22; F24H 1/00; F24H 9/00

(52) U.S. Cl. CPC F24H 1/101; B60H 1/2221; F24H 1/009; F24H 9/0015

(57) ABSTRACT

The present invention is characterized by comprising: a main body provided with a plate-shaped partition wall part; a circuit board located on one surface of the partition wall part; a heat-generating plate positioned so as to face the other surface of the partition wall part; a bus bar electrically connecting the heat-generating plate and the circuit board; and a flow path located between the partition wall part and the heat-generating plate. The flow path includes a plurality of straight flow paths and a plurality of curved flow paths, and a plurality of heat-dissipating fins are arranged on at least one among the partition wall part and the heat-generating plate that form the flow path.

### TECHNICAL FIELD

The present invention relates to a fluid heating heater, and more specifically, to a fluid heating heater with improved heat radiation function.

### BACKGROUND ART

Currently, the most common vehicles use engines as driving sources. Engines use gasoline, diesel, and the like as energy sources, and these energy sources have various problems such as environmental pollution as well as reducing oil reserves. Accordingly, the need for new energy sources is gradually emerging, and vehicles, such as electric vehicles, using new energy sources are being developed or are reaching the stage of practical use.

However, since electric vehicles do not have heat sources which generate a large amount of heat like engines, it is necessary to install additional heat sources to be used in vehicle air conditioning systems.

Heat sources installed in conventional electric vehicles include heat pumps and electric heaters, and the like, and among them, electric heaters are widely used because they can be used without significantly changing designs of existing air conditioning systems. The electric heaters are mainly divided into air heating heaters, which directly heat air which is blown into a vehicle, and fluid heating heaters (or cooling water heaters) which indirectly heat air by heating cooling water which exchanges heat with the air.

### RELATED ART

### Patent Document 1) Korean Laid-open Patent No. 10-2018-0005410 (Jan. 16, 2018, COOLING-WATER HEATER.)

### TECHNICAL PROBLEM

The present invention is directed to improving heat transfer efficiency of a product by improving heat radiation performance.

The present invention is also directed to improving durability of a fluid heating heater.

Objectives to be solved through the present invention are not limited to the above-described objectives, and other objectives which are not described above will be clearly understood by those skilled in the art through the following description.

### TECHNICAL SOLUTION

One aspect of the present invention provides a fluid heating heater including a main body including a partition wall part having a plate shape, a heating plate positioned to face the other surface of the partition wall part, a circuit board disposed on one surface of the partition wall part, a busbar which electrically connects the heating plate and the circuit board, and a flow path disposed between the partition wall part and the heating plate, wherein the flow path includes a plurality of straight flow paths and a plurality of curved flow paths, and a plurality of heat-radiating fins are disposed on at least one side of the partition wall part and the heating plate which form the flow path.

Preferably, the flow path may include a plurality of straight portions and a plurality of curved portions.

Preferably, a turning vane may be disposed in a space between the curved portion that are disposed to face the inner surface of the curved portion.

Preferably, a length from a center line of the turning vane to an exit may be formed to be greater than a length from the center line of the turning vane to an entrance.

Preferably, the turning vane at the exit may be formed parallel to a formation direction of the straight portion.

Preferably, at least one guide vane may be disposed between the turning vane and the curved portion.

Preferably, the guide vane may have the same curvature as the curved portion.

Preferably, the heat-radiating fins may be disposed on the straight flow paths.

Preferably, the heat-radiating fins may be disposed in a zigzag manner.

Preferably, the heat-radiating fin may be a column having a circular cross section.

Preferably, the heat-radiating fin may be a column having a cross section of a rain drop shape.

Preferably, the heat-radiating fin may be a column having a diamond-shaped cross section.

Preferably, the flow path may have an inlet and an outlet, and the heat-radiating fins may be disposed to extend toward the outlet.

Preferably, the guide vane may be provided as a plurality of guide vanes, and a distance between the plurality of heat-radiating fins disposed perpendicular to the straight portions may be formed to be greater than a distance between the guide vanes.

### ADVANTAGEOUS EFFECTS

According to embodiments, since a partition serves as a rib, there are effects of minimizing the deformation of a product and reducing the risk of cooling water leakage.

In addition, since heat radiation performance is improved, there is an effect of improving heat transfer efficiency of a product.

In addition, since heat energy of a heating element is easily transferred to cooling water, there is an effect of improving durability by lowering a temperature of the heating element.

Various beneficial advantages and effects of the present invention are not limited to the above-described contents and may be more easily understood in the process of describing specific embodiments of the present invention.

### BRIEF DESCRIPTION OF THE DRAWINGS

FIG. 1 is a perspective view illustrating a fluid heating heater according to one embodiment of the present invention.

FIGS. 2 and 3 are exploded perspective views of FIG. 1.

FIG. 4 is a front view illustrating a state in which a first cover is separated from the fluid heating heater in FIG. 1.

FIG. 5 is a rear view illustrating a state in which a second cover is separated from the fluid heating heater in FIG. 1.

FIG. 6 is a cross-sectional view along line A-A in FIG. 1.

FIG. 7 is a cross-sectional view along line B-B in FIG. 1.

FIG. 8 is a front view of a main body of FIG. 2.

FIG. 9 is a rear view of the main body of FIG. 2.

FIG. 10 is a view illustrating a structure of a heating plate which is a component of FIG. 1.

FIG. 11 is view of an effect analysis material of a heat-radiating fin illustrated in FIG. 10.

FIG. 12 is a view of a heat radiation structure and an effect analysis material of a curved pipe part in FIG. 10.

FIG. 13 is a view showing an effect of structural improvement according to the embodiment of the present invention.

### MODES OF THE INVENTION

Hereinafter, exemplary embodiments of the present invention will be described in detail with reference the accompanying drawings.

However, the technical spirit of the present invention is not limited to some embodiments which will be described and may be implemented in a variety of different forms, and one or more components of the embodiments may be selectively combined, substituted, and used within the range of the technical spirit of the present invention.

In addition, unless clearly and specifically defined otherwise by the context, all terms (including technical and scientific terms) used herein may be interpreted as having meanings customarily understood by those skilled in the art, and the meanings of generally used terms, such as those defined in commonly used dictionaries, will be interpreted in consideration of contextual meanings of the related art.

In addition, the terms used in the embodiments of the present invention are considered in a descriptive sense only and not to limit the present invention.

In the present specification, unless specifically indicated otherwise by the context, singular forms include plural forms, and in a case in which “at least one (or one or more) among A, B, and C” is described, this may include at least one combination among all possible combinations of A, B, and C.

In addition, in descriptions of components of the present invention, terms such as “first,” “second,” “A,” “B,” “(a),” and “(b)” may be used.

The terms are only to distinguish one component from another component, and the essence, order, and the like of the components are not limited by the terms.

In addition, it should be understood which, when a first component is referred to as being “connected” or “coupled” to a second component, such a description may include both a case in which the first component is directly connected or coupled to the second component, and a case in which the first component is connected or coupled to the second component with a third component disposed therebetween.

In addition, when a first component is described as being formed or disposed “on” or “under” a second component, such a description includes both a case in which the two components are formed or disposed in direct contact with each other and a case in which one or more other components are interposed between the two components. In addition, when the first component is described as being formed “on” or “under” the second component, such a description may include a case in which the first component is formed at an upper side or a lower side with respect to the second component.

Hereinafter, when embodiments are described in detail with reference to the accompanying drawings, components which are the same or correspond to each other will be denoted by the same or corresponding reference numerals in all drawings, and redundant descriptions will be omitted.

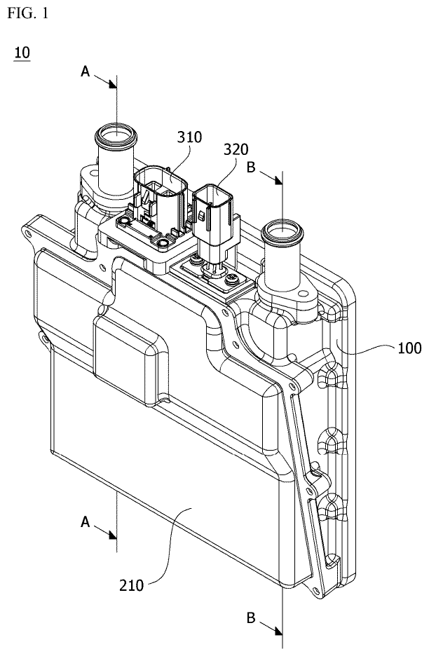

FIGS. 1 to 13 are views illustrating main feature parts in order to clearly understand a concept of the present invention, and as a result, various variations of the drawings are expected, and the scope of the present invention does not need to be limited by specific shapes illustrated in the drawings.

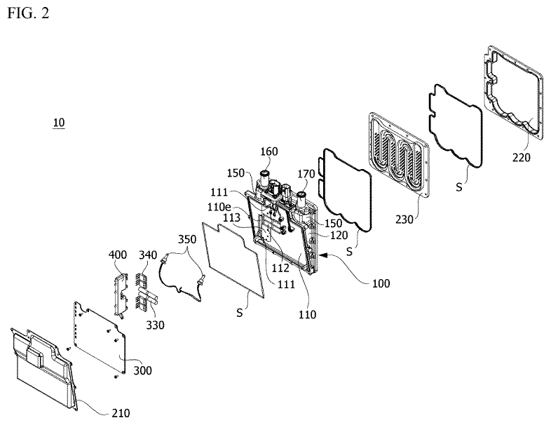

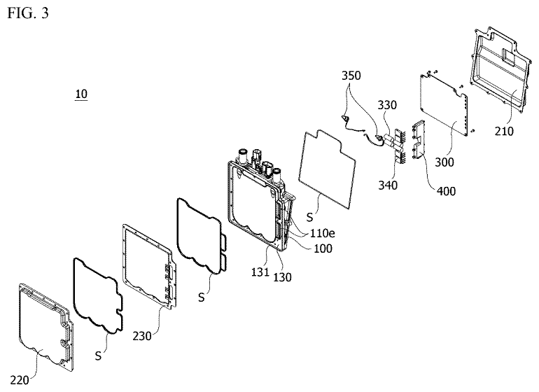

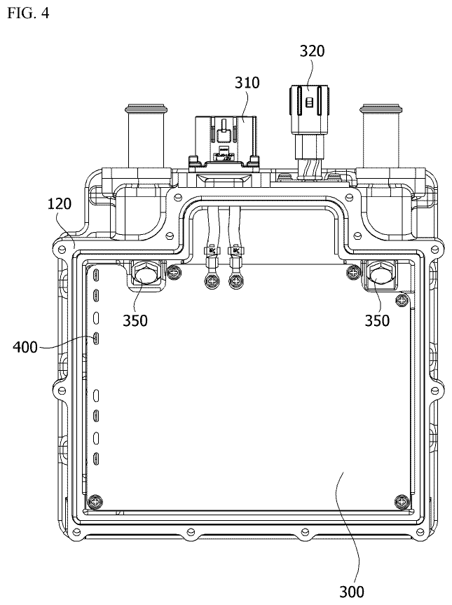

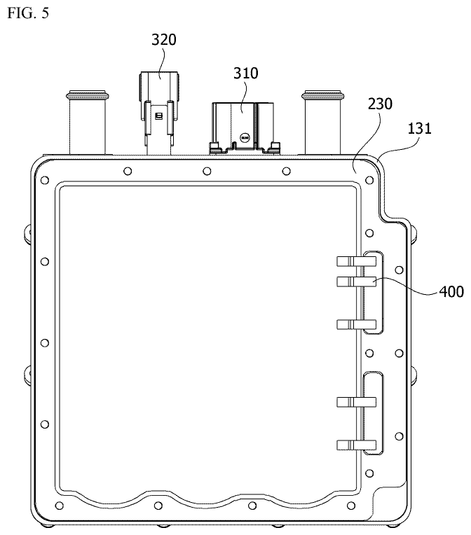

FIG. 1 is a perspective view illustrating a fluid heating heater according to one embodiment of the present invention, and FIGS. 2 and 3 are exploded perspective views of FIG. 1. FIG. 4 is a front view illustrating a state in which a first cover is separated from the fluid heating heater in FIG. 1, and FIG. 5 is a rear view illustrating a state in which a second cover is separated from the fluid heating heater in FIG. 1.

Referring to FIGS. 1 to 5, a fluid heating heater 10 according to one embodiment of the present invention may include a main body 100, a first cover 210, a second cover 220, a heating plate 230, a circuit board 300 and a busbar 400, and may further include a first connector 310, a second connector 320, electronic elements 330 and 340, and/or a water temperature sensor 350.

The main body 100 may include a partition wall part 110, a first sidewall part 120, a second sidewall part 130, and a pair of protruding parts 150.

The partition wall part 110 may have a plate shape including one surface and the other surface opposite to the one surface.

The first sidewall part 120 may be disposed on one surface of the partition wall part 110, and the second sidewall part 130 may be disposed on the other surface of the partition wall part 110.

The pair of protruding parts 150 may be disposed on one surface of the partition wall part 110. The pair of protruding parts 150 may be coupled to a fluid supply pipe 160 and a fluid discharge pipe 170.

The fluid supply pipe 160 may supply a fluid to a flow path 235, and the fluid discharge pipe 170 may discharge the fluid from the flow path 235.

The first cover 210 may be coupled to the first sidewall part 120 by a fastening member such as a bolt and may form a first accommodation space in front of the main body 100. The second cover 220 may be coupled to the second sidewall part 130 by a fastening member such as a bolt and may form a second accommodation space behind the main body 100. Sealing members S for improving watertightness, such as O-rings, may be interposed between the first cover 210 and the main body 100, between the second cover 220 and the heating plate 230, and between the heating plate 230 and the main body 100,.

The heating plate 230 may be positioned to face the other surface of the partition wall part 110. For example, a straight portion and a curved portion of the flow path 235 may be in contact with the other surface of the partition wall part 110.

The heating plate 230 and the second cover 220 may be coupled to the second sidewall part 130 by a fastening member such as a bolt. The second sidewall part 130 may include an edge portion 131 which is stepped to allow the heating plate 230 to be inserted into the second sidewall part 130. The edge portion 131 may protrude along an edge of the second sidewall part 130 to support a side surface of the heating plate 230.

The circuit board 300 may be disposed inside the first sidewall part 120. In addition, the circuit board 300 may be coupled to a plurality of posts 111 protruding from one surface of the partition wall part 110 by a fastening member such as a bolt. Accordingly, the circuit board 300 may be disposed to be spaced apart from one surface of the partition wall part 110, and a space, in which the electronic elements 330 and 340 are disposed, may be secured between the circuit board 300 and one surface of the partition wall part 110.

The first connector 310 and the second connector 320 may pass through the first sidewall part 120 to electrically connect an external power supply (not shown) and the circuit board 300. The first connector 310 may be a high-voltage connector (HV connector), and the second connector 320 may be a low-voltage connector (LV connector). The circuit board 300 may receive electricity from an external power source through the first connector 310 and the second connector 320.

The electronic elements 330 and 340 may be disposed in a seating groove 112 or platform 113 which is formed on one surface of the partition wall part 110. Accordingly, the electronic elements 330 and 340 may exchange heat with the fluid flowing along a flow path 141, wherein the partition wall part 110 is interposed between the electronic elements 330 and 340 and the flow path 141. Accordingly, over heating of the electronic elements 330 and 340 can be prevented, and energy efficiency can also be improved by heating the fluid using heat emitted from the electronic elements 330 and 340.

The electronic elements 330 and 340 may be electrically connected to the circuit board 300 to implement various control logics along with circuit patterns (not shown), devices (not shown), and the like printed or mounted on the circuit board 300. The electronic elements 330 and 340 may include capacitors 330, insulated gate bipolar transistors (IGBTs) 340, and the like, but are not limited thereto.

The busbar 400 may be disposed in a connecting hole 110e passing through the partition wall part 110 to electrically connect a heating pattern of the heating plate 230 and the circuit board 300. The heating pattern of the heating plate 230 may receive electricity through the busbar 400. The heating pattern may be an electrical resistor which is heated when receiving electricity. Meanwhile, the connecting hole 110e may pass through the partition wall part 110 inside the first sidewall part 120 and the second sidewall part 130.

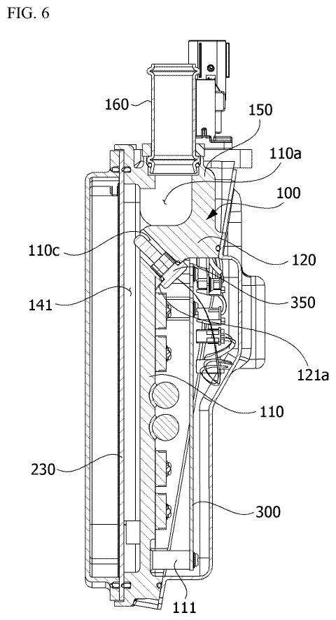

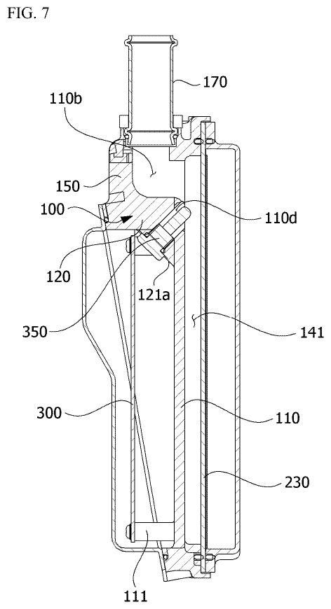

FIG. 6 is a cross-sectional view along line A-A in FIG. 1, and FIG. 7 is a cross-sectional view along line B-B in FIG. 1.

Referring to FIGS. 6 and 7, the main body 100 may include an inlet 110a and an outlet 110b passing through the partition wall part 110 from the outside of the first sidewall part 120.

The inlet 110a and the outlet 110b may be connected to the flow path 141 and may extend into the pair of protruding parts 150 to be connected to the fluid supply pipe 160 and the fluid discharge pipe 170, respectively.

A pair of water temperature sensors 350 may be disposed in a pair of insertion holes 110c and 110d passing through the partition wall part 110. The insertion holes 110c and 110d may be connected to the flow path 141 inside the first sidewall part 120 through the partition wall part 110. In addition, the pair of insertion holes 110c and 110d may be disposed in positions corresponding to the inlet 110a and the outlet 110b, respectively. That is, the pair of insertion holes 110c and 110d may be disposed to face the inlet 110a and the outlet 110b with the first sidewall part 120 interposed therebetween. Accordingly, the pair of water temperature sensors 350 may measure a temperature of the fluid immediately after entering the flow path 141 and a temperature of the fluid just before being discharged from the flow path 141. Meanwhile, the circuit board 300 may receive temperature data from the pair of water temperature sensors 350 and adjust power supplied to the heating plate 230 so that a temperature of the fluid discharged from the flow path 141 reaches a predetermined target temperature.

The pair of insertion holes 110c and 110d may be disposed in a pair of inclined surfaces 121a. The inclined surfaces 121 a may be disposed to be inclined with respect to one surface of the partition wall part 110 and connected to an inner side surface of the first sidewall part 120. The insertion holes 110c and 110d may extend in a direction inclined with respect to one surface of the partition wall part 110. Accordingly, a problem that a jig (not shown), which holds and transfers the water temperature sensors 350, may collide with the first sidewall part 120 when the water temperature sensors 350 are installed or replaced can be solved. The insertion holes 110c and 110d may extend perpendicularly to the inclined surfaces 121a, but are not necessarily limited thereto.

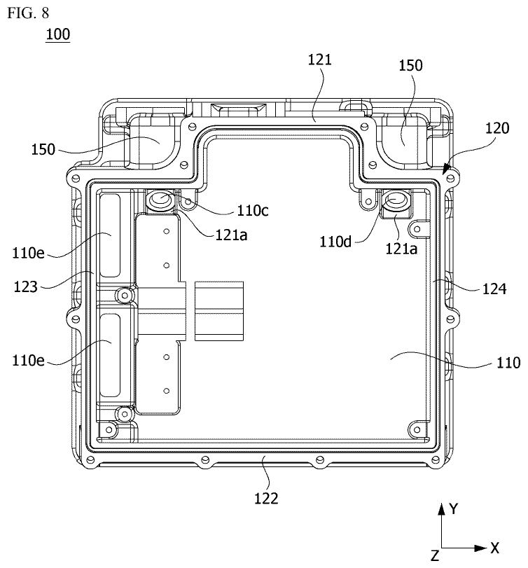

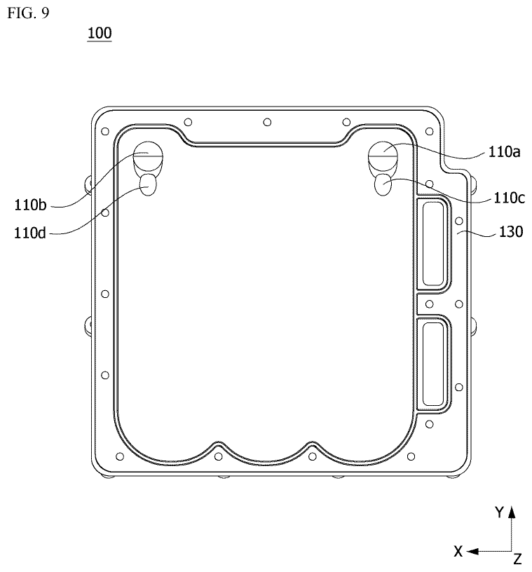

FIG. 8 is a front view of the main body of FIG. 2, and FIG. 9 is a rear view of the main body of FIG. 2.

Referring to FIGS. 8 and 9, the first sidewall part 120 may include a 1-1 sidewall 121 and a 1-2 sidewall 122 facing each other, and a 1-3 sidewall 123 and a 1-4 sidewall 124 which connect the 1-1 sidewall 121 and the 1-2 sidewall 122 and face each other.

An inner side surface of the 1-1 sidewall 121 may be connected to the pair of inclined surfaces 121a, and an outer side surface of the 1-1 sidewall 121 may be connected to the pair of protruding parts 150. The pair of inclined surfaces 121a may be disposed to face the pair of protruding parts 150.

Referring to FIGS. 4 and 8, the first connector 310 and the second connector 320 may be positioned to pass through the 1-1 sidewall 121. In addition, the first connector 310 and the second connector 320 may be disposed between the pair of protruding parts 150 or between the pair of inclined surfaces 121a.

Referring to FIG. 9, the inlet 110a and the outlet 110b may be disposed in the other surface of the partition wall part. The inlet 110a and the outlet 110b may be connected to a flow path entrance 236 and a flow path exit 237 which are disposed between the partition wall part and the heating plate.

In addition, the pair of insertion holes 110c and 110d may be disposed adjacent to the inlet 110a and the outlet 110b, respectively.

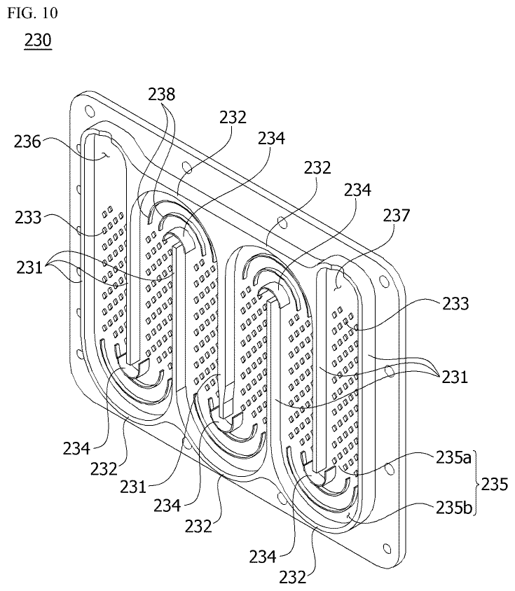

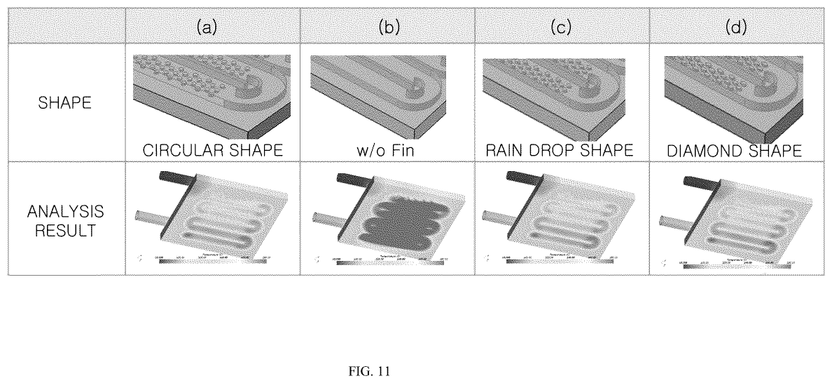

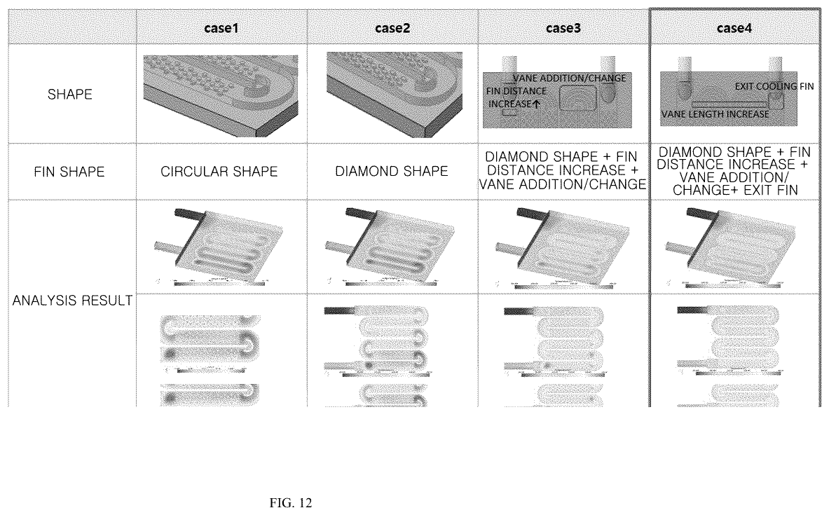

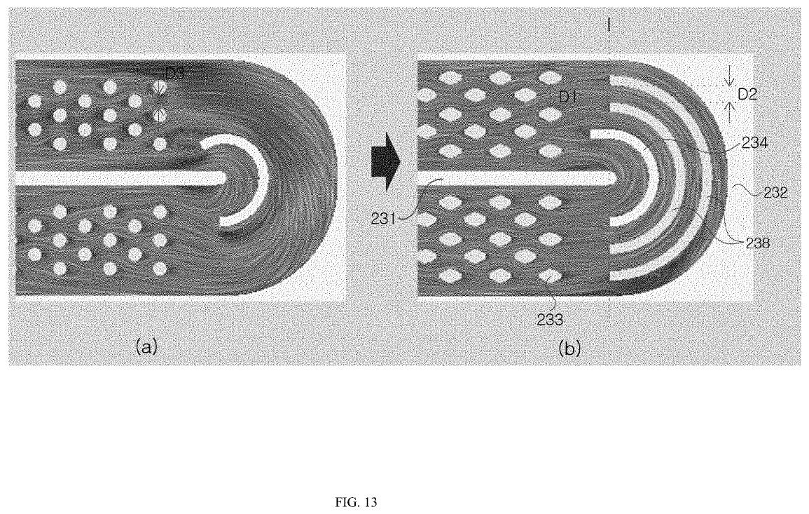

FIG. 10 is a view illustrating a structure of the heating plate which is a component of FIG. 1, and FIG. 11 is view of an effect analysis material of a heat-radiating fin illustrated in FIG. 10. FIG. 12 is a view of a heat radiation structure and an effect analysis material of a curved pipe part in FIG. 10, and FIG. 13 is a view showing an effect of structural improvement according to the embodiment of the present invention.

Referring to FIGS. 10 to 13, the fluid heating heater 10 according to the embodiment of the present invention may include the main body 100 including the partition wall part 110 having a plate shape, the heating plate 230 disposed to face the other surface of the partition wall part 110, the circuit board 300 disposed on one surface of the partition wall part 110, the busbar 400 which electrically connects the heating plate 230 and the circuit board 300, and the flow path 235 disposed between the partition wall part 110 and the heating plate 230, the flow path 235 may include a plurality of straight flow paths 235a and a plurality of curved flow paths 235b, and a plurality of heat-radiating fins 233 may be disposed on at least one side of the partition wall part 110 and the heating plate 230 forming the flow path 235.

In the description of the present invention, a structure in which the straight portions 231 and the curved portions 232 of the flow path 235 are connected to the heating plate 230 is described, but the present invention is limited thereto, the flow path 235 may be disposed on the other surface of the partition wall part 110 of the main body 100, and may be divided and disposed on the heating plate 230 and the main body 100.

The flow path 235 may be disposed on the heating plate 230 and formed by coupling the plural straight portions 231 and the plurality of curved portions 232.

The plurality of straight portions 231 may be provided to be disposed parallel to each other, and the straight flow paths 235a may be formed between adjacent straight portions 231 of the flow path 235.

The curved portions 232 may connect the straight portions 231 and the straight portions 231 to form curved flow paths 235b.

The straight portions 231 and the curved portions 232 may be interconnected to form one flow path 235, and a flow path entrance 236 and a flow path exit 237 may be formed at end portions of the flow path 235.

The plurality of heat-radiating fins 233 may be disposed in the flow path 235 formed by coupling of the plurality of straight portions 231 and the plurality of curved portions 232. The heat-radiating fins 233 may be disposed in regions of the straight flow paths 235a, and the plurality of heat-radiating fins 233 may be disposed in a zigzag manner. Such zigzag arrangement may maximize a flow contact area between cooling water and the heat-radiating fins 233.

In the heat-radiating fin 233, any one among a column having a cross section of a circular shape, a column having a cross section of a rain drop shape, and a column having a diamond-shape cross section may be used.

In this case, the cross section of the circular shape may include a circular or oval shape.

The cross section of the water drop shape may be a cross section of a shape in which one side having a semicircular shape is connected to the other side having a triangular shape.

In addition, the column having the diamond-shaped cross section may be a column having a diamond-shaped cross section and include a column having a shape of which a vertex is rounded.

The shape of the heat-radiating fin 233 is not necessarily limited thereto and may be changed into any one of various shapes.

The heat-radiating fin 233 may transfer heat generated by a heating element to the cooling water to improve cooling efficiency. In this case, a height of the heat-radiating fin 233 may be determined within a range that a pressure drop is minimized. As one example, the height of the heat-radiating fin 233 may be determined within the range of 20 to 50% of a total height of the flow path 235.

FIG. 11A shows a test result of the heat-radiating fin 233 having the circular shape, FIG. 11B shows a test result when the heat-radiating fin 233 is not present, FIG. 11C shows a test result of the heat-radiating fin 233 having the rain drop shape, and FIG. 11D shows a test result of the heat-radiating fin 233 having the diamond shape.

Referring to FIG. 11, pressure drop and temperature reduction effects according to a shape of the heat-radiating fin 233 can be evaluated. When the heat-radiating fin 233 is not present, it can be seen that a pressure drop is the lowest, a temperature is the highest, and thus, heat radiation performance is degraded.

Meanwhile, when the heat-radiating fin 233 is present, it can be seen that temperature distributions are similar to each other when the shapes are the circular shape, the rain drop shape, and the diamond shape.

These results can show that the shape of the fin does not significantly affect the heat radiation effect, and it can be seen that a pressure drop is minimized in the diamond shape when the heat-radiating fin 233 is present. Accordingly, it can be seen that the shape of the heat-radiating fin 233 can be improved to reduce the pressure drop.

A turning vane 234 may be disposed in a space between an inner surface of the curved portion 232 and the straight portion 231 disposed to face the inner surface, that is, in front of the curved portion 232.

The turning vane 234 may be disposed adjacent to an end portion of the straight portion 231 and can prevent a flow of the entire cooling water flowing into the curved portion 232 from being biased to a wall surface.

A length from a center line of the turning vane to an exit may be formed to be greater than a length from the center line of the turning vane to an entrance. In this case, the turning vane 234 at the exit may be formed parallel to a formation direction of the straight portion 231.

Referring to FIGS. 13, FIG. 13A is a view showing a flow along the turning vane 234 disposed such that the side of the exit of the turning vane 234 faces the wall surface, and FIG. 13B is a view showing a flow along of the turning vane 234 disposed such that the turning vane 234 at the exit is disposed parallel to the formation direction of the straight portion 231.

In FIG. 13, it can be seen that a flow can be improved and a biasing toward the wall surface can be reduced when the side of the exit of the turning vane 234 is disposed parallel to the formation direction of the straight portion 231 compared to when disposed to face the wall surface.

At least one guide vane 238 may be disposed between the turning vane 234 and the curved portion 232. In this case, the guide vane 238 and the curved portion 232 may have the same curvature to smooth the flow.

As an example, the guide vane 238 may be provided as a plurality of guide vanes 238.

The guide vane 238 may be disposed in the curved portion 232 to guide the flow of the cooling water and may serve a heat radiation function.

When the guide vane 238 is disposed as illustrated in FIG. 13, it can be seen that a heat radiation area is increased and the heat radiation performance is improved compared to when the guide vane 238 is not present.

In addition, in the present invention, a distance between the fins may be increased to reduce a flow bias to improve the heat radiation performance.

Referring to FIG. 13, it can be seen that the distance between the heat-radiating fins 233 is increased to reduce the flow bias so that the heat radiation performance is improved.

For example, a distance D1 between the plurality of heat-radiating fins 233 disposed in a direction perpendicular to the straight portion 231 may be formed to be greater than a distance D2 between the guide vanes 238.

FIG. 12 is a view of a heat radiation structure and an effect analysis material of the heating plate 230 in FIG. 10.

Referring to FIG. 12, case 1 shows an experimental result when only the circular heat-radiating fin 233 is used, case 2 shows an experimental result when only the diamond-shaped heat-radiating fin 233 is used, case 3 shows an experimental result when the diamond-shaped heat-radiating fin 233 is used, the distance between the heat-radiating fins 233 is increased, and the vane is added, and case 4 shows an experimental result when exit fins are additionally used from case 3.

It can be seen that a pressure drop in case 2 is the lowest, and heat radiation performance in case 4 is the best.

According to analysis of these results, it can be seen that, when the guide vane 238 is added, the pressure drop is increased, and when the distance between and arrangement of the fins are improved, and the guide vane 238 is added, an effect of temperature reduction is improved.

In case 4, it can be seen that a temperature reduction effect is significantly improved compared to the pressure drop.

As described above, the embodiments of the present have been specifically described with reference to the accompanying drawings.

The above description is only an example describing the technical spirit of the present invention, and various changes, modifications, and replacements may be made by those skilled in the art without departing from the essential characteristics of the present invention. Therefore, the disclosed embodiments and accompanying drawings in the present invention are considered in a descriptive sense only and not for purposes of limitation, and the scope of the invention is not limited by the embodiments. It should be interpreted which the scope of the invention is defined by the appended claims and encompasses all modifications and equivalents which fall within the scope of the appended claims.

### REFERENCE NUMERALS

10: FLUID HEATING HEATER
110: PARTITION WALL PART
110B: OUTLET
110E: CONNECTING HOLE
112: SEATING GROOVE
120: FIRST SIDEWALL PART
121A: INCLINED SURFACE
123: 1-3 SIDEWALL
130: SECOND SIDEWALL PART
150: PROTRUDING PART
170: FLUID DISCHARGE PIPE
220: SECOND COVER
231: STRAIGHT PORTION
233: HEAT-RADIATING FIN
235: FLOW PATH
235B: CURVED FLOW PATH
237: FLOW PATH EXIT
300: CIRCUIT BOARD
320: SECOND CONNECTOR
350: WATER TEMPERATURE SENSOR

What is claimed is:

1. A fluid heating heater comprising:
a main body including a partition wall part having a plate shape;
a heating plate positioned to face the other surface of the partition wall part;
a circuit board disposed on one surface of the partition wall part;
a busbar which electrically connects the heating plate and the circuit board; and
a flow path disposed between the partition wall part and the heating plate,
wherein the flow path includes a plurality of straight flow paths and a plurality of curved flow paths, and
a plurality of heat-radiating fins are disposed on at least one side of the partition wall part and the heating plate which form the flow path.

2. The fluid heating heater of claim 1, wherein the flow path includes:
a plurality of straight portions; and
a plurality of curved portions.

3. The fluid heating heater of claim 2, wherein a turning vane may be disposed in a space between the curved portion that are disposed to face the inner surface of the curved portion.

4. The fluid heating heater of claim 3, wherein a length from a center line of the turning vane to an exit is formed to be greater than a length from the center line of the turning vane to an entrance.

5. The fluid heating heater of claim 4, wherein the turning vane at the exit is formed parallel to a formation direction of the straight portion.

6. The fluid heating heater of claim 3, wherein at least one guide vane is disposed between the turning vane and the curved portion.

7. The fluid heating heater of claim 6, wherein the guide vane has the same curvature as the curved portion.

8. The fluid heating heater of claim 1, wherein the heat-radiating fins are disposed on the straight flow paths.

9. The fluid heating heater of claim 8, wherein the heat-radiating fins are disposed in a zigzag manner.

10. The fluid heating heater of claim 8, wherein the heat-radiating fin includes a column having a circular cross section.

11. The fluid heating heater of claim 8, wherein the heat-radiating fin includes a column having a cross section of a rain drop shape.

12. The fluid heating heater of claim 8, wherein the heat-radiating fin includes a column having a diamond-shaped cross section.

13. The fluid heating heater of claim 1, wherein:
the flow path has an inlet and an outlet; and
the heat-radiating fins are disposed to extend toward the outlet.

14. The fluid heating heater of claim 6, wherein:
the guide vane is provided as a plurality of guide vanes; and
a distance between the plurality of heat-radiating fins disposed perpendicular to the straight portions is formed to be greater than a distance between the guide vanes.
